(19) United States
(12) Patent Application Publication
(10) Pub. No.: US 2021/0337685 A1
(43) Pub. Date: Oct. 28, 2021

(54) PORTABLE ELECTRONIC DEVICE CASE

(71) Applicant: ExtComfort International Group Co. Limited, Hong Kong (CN)

(72) Inventor: Junjie Li, Shenzhen (CN)

(21) Appl. No.: 16/858,936

(22) Filed: Apr. 27, 2020

(51) Int. Cl. H05K 5/02; H05K 5/00

(52) U.S. Cl. CPC H05K 5/0217; H05K 5/0047

(57) ABSTRACT

Systems and methods for protecting an electronic device are described. Embodiments of the systems and methods may include a zipper extending along at least a first side and a second side of the protective case, a zipper slider configured to be located along the second side when the zipper is fully closed, an inner flap that extends in a first direction parallel to the first side from the second side to a third side of the protective case opposite the second side, and an extension of the inner flap adjacent to the second side, wherein the extension extends in a second direction parallel to the second side such that a width of the inner flap adjacent to the second side is greater than a width of the inner flap adjacent to the third side.

### BACKGROUND

The following relates generally to device accessories, and more specifically to a case for protecting an electronic device.

Electronic devices can be fragile, and are often protected using external accessories such as cases or covers. In some cases, a protective apparatus (i.e., a case or a cover) may include a zipper for closing the apparatus around the electronic device. However, the zipper slider may press against the device and cause scratches or other damage to the device. Therefore, there is a need in the art for systems and methods to prevent a zipper from scratching an electronic device within a protective case.

### SUMMARY

An apparatus, method, and process for protecting an electronic device are described. Embodiments of the apparatus, method, and process may include a zipper extending along a first side and at least a part of a second side of the protective case, a zipper slider configured to be located along the second side when the zipper is fully closed, an inner flap that extends in a first direction parallel to the first side from the second side to a third side of the protective case opposite the second side, and an extension of the inner flap adjacent to the second side, wherein the extension extends in a second direction parallel to the second side such that a width of the inner flap adjacent to the second side is greater than a width of the inner flap adjacent to the third side.

### BRIEF DESCRIPTION OF THE DRAWINGS

FIG. 1 shows an example of a protective case for an electronic device according to aspects of the present disclosure.

FIG. 2 shows an example of a zipper of a protective case according to aspects of the present disclosure.

FIG. 3 shows an example of a process for manufacturing an apparatus for protecting an electronic device according to aspects of the present disclosure.

FIG. 4 shows an example of a process for using an apparatus for protecting an electronic device according to aspects of the present disclosure.

### DETAILED DESCRIPTION

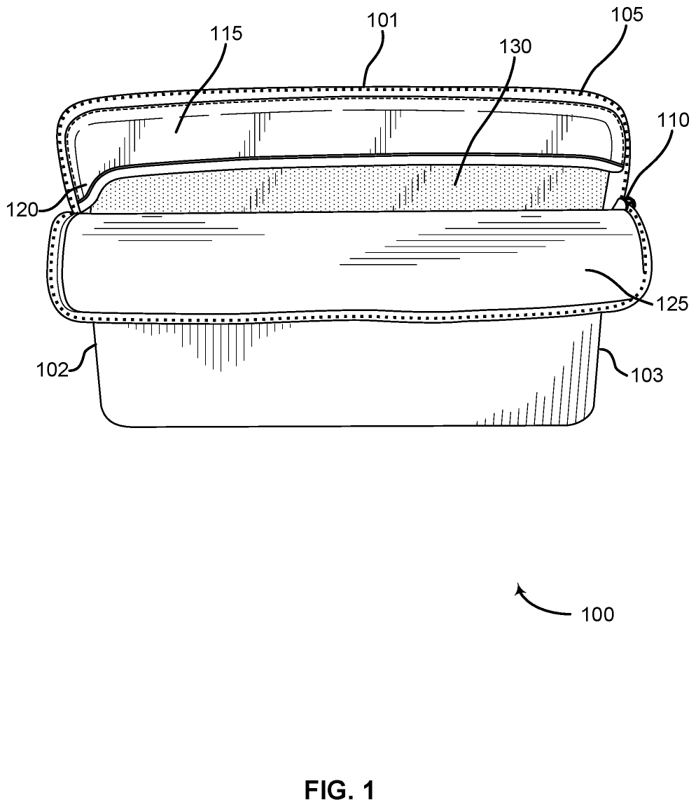

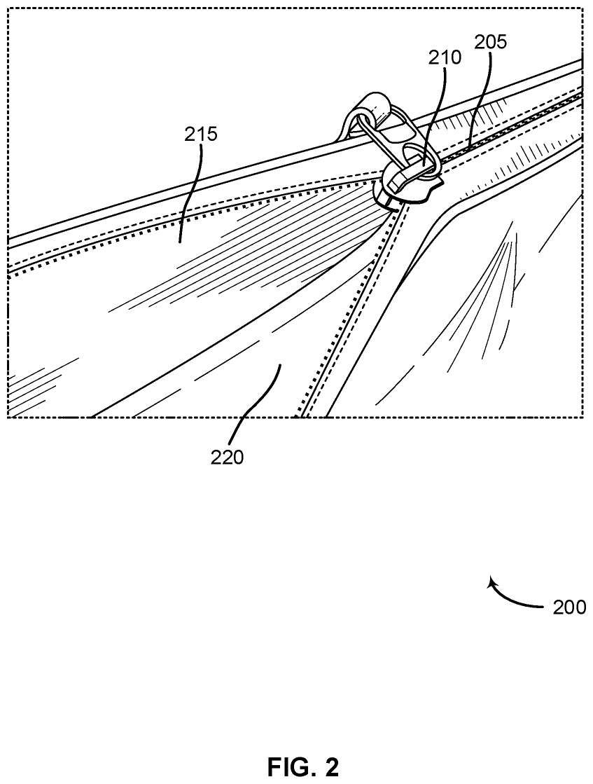

FIG. 1 shows an example of a protective case 100 for an electronic device 130 according to aspects of the present disclosure. The example shown includes protective case 100 and electronic device 130. Protective case 100 includes first side 101, second side 102, and third side 103. Protective case 100 may be an example of, or include aspects of, the corresponding element or elements described with reference to FIG. 2. Protective case 100 may include zipper 105, inner flap 115, and lining 125.

Zipper 105 may extend along a first side 101 and at least a part of a second side 102 of the protective case 100. In some examples, the zipper 105 extends across a full length of the first side 101, and along a partial length of the second side 102 and a partial length of the third side 103. Zipper 105 may be an example of, or include aspects of, the corresponding element or elements described with reference to FIG. 2.

Zipper 105 may include zipper slider 110. Zipper slider 110 may be configured such that it is located along the second side 102 when the zipper 105 is fully closed. In some examples, the zipper slider 110 is located along the third side when the zipper 105 is fully open. Zipper slider 110 may be an example of, or include aspects of, the corresponding element or elements described with reference to FIG. 2.

Inner flap 115 may extend in a first direction parallel to the first side 101 from the second side 102 to the third side 103 opposite the second side. In some examples, the inner flap 115 is configured to separate at least a portion of the electronic device 130 from the zipper slider 110. In some examples, the inner flap 115 is not located between the zipper slider 110 and the electronic device 130 when the zipper is fully open. That is, to enable easy insertion of the electronic device 130 into the protective case 100, the inner flap may not be extended on the side adjacent to where the zipper slider is located when it is open.

In some examples, the inner flap 115 includes an elastic material configured to enable insertion of the electronic device 130 in the protective case 100 with at least one edge of the electronic device 130 covered by the inner flap 115. Inner flap 115 may be an example of, or include aspects of, the corresponding element or elements described with reference to FIG. 2.

Inner flap 115 may include extension 120. Extension 120 may include the portion of the inner flap 115 adjacent to the second side, wherein the extension 120 extends in a second direction parallel to the second side 102 such that a width of the inner flap 115 adjacent to the second side 102 is greater than a width of the inner flap 115 adjacent to the third side 103.

For example, the inner flap 115 may have a width of about one to three inches along most of its length along the first side 101. However, close to the second side 102 (i.e., where the zipper slider 110 is located when it is fully closed), the inner flap may have an extension that extends to within one half inch of where the zipper slider 110 is located in the closed position. Thus, the width of the inner flap may increase by about one half inch to two inches in the region within one or two inches of the second side 103. Accordingly, the extension 120 of the inner flap 115 is configured to separate the zipper slider 110 from the electronic device 130 when the zipper 105 is fully closed.

In an alternative embodiment, the inner flap has a constant increase in width as it extends from the third side 103 to the second side 102. In yet another embodiment, the extension 120 may extend several inches toward the third side (i.e., a curved portion at the edge of the extension 120 may be located anywhere along the bottom of the inner flap 115, but preferably within two inches of the second side 102.

Lining 125 may be located on at least one interior surface of the protective case 100. Lining may include a soft material configured to prevent damage and scratching to the electronic device 130. Lining 125 may be an example of, or include aspects of, the corresponding element or elements described with reference to FIG. 2.

FIG. 2 shows an example of a zipper 205 of a protective case 200 according to aspects of the present disclosure. Protective case 200 may be an example of, or include aspects of, the corresponding element or elements described with reference to FIG. 1.

Protective case 200 may include zipper 205, inner flap 215, and lining 220. Zipper 205 may be an example of, or include aspects of, the corresponding element or elements described with reference to FIG. 1.

Zipper 205 may include zipper slider 210. Zipper slider 210, inner flap 215, and lining 220 may be examples of, or include aspects of, the corresponding element or elements described with reference to FIG. 1.

In the embodiment shown in FIG. 2, the zipper slider 210 is in a partially closed position. Without the inner flap 215, the zipper slider 210 might scratch an electronic device located in the protective case 200. However, an edge of the electronic device is tucked within the inner flap 215 such that the zipper slider 210 does not contact the electronic device (not shown, because it is under the inner flap 215). In the fully open position, the inner flap 215 may not come directly between the zipper slider 210 and the electronic device because that may cause difficulty in inserting the electronic device into the protective case. However, in the fully closed position, and extension of the inner flap 215 may extend approximately as far as the zipper 205 so that it protects the electronic device from being scratched by the zipper slider 210.

It should be noted that because the protective case may be just big enough to contain the electronic device, there may be a force pressing the zipper slider toward the electronic device when the zipper 205 is at least partially closed. However, this force may be greater when the zipper 205 is closed (or partially closed) than when it is open. Therefore, an extension of the inner flap 215 may provide sufficient protection if it is located along the portion of the zipper 205 where the zipper slider 210 is located in a closed position, but not along the opposite side where the zipper slider is located in the open position.

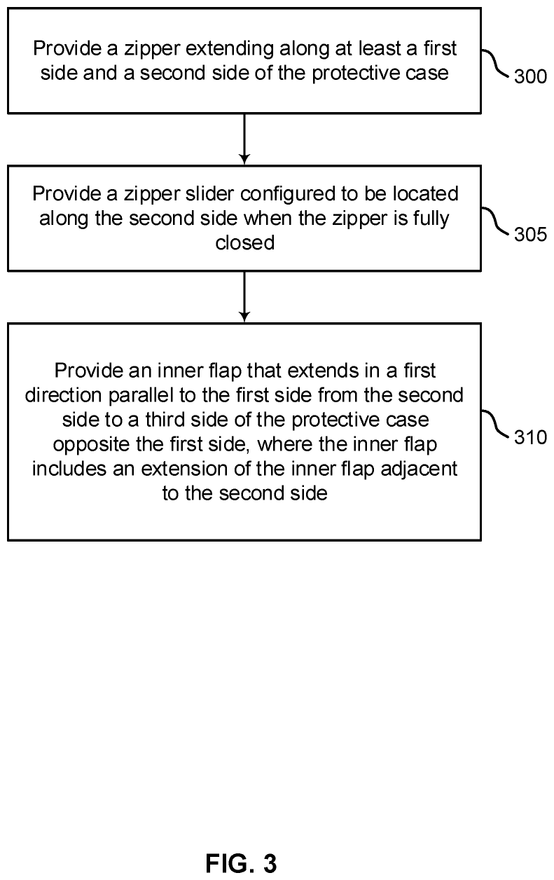

FIG. 3 shows an example of a process for manufacturing an apparatus for protecting an electronic device according to aspects of the present disclosure. In some examples, these operations may be performed by a system including a processor executing a set of codes to control functional elements of an apparatus. Additionally or alternatively, the processes may be performed using special-purpose hardware. Generally, these operations may be performed according to the methods and processes described in accordance with aspects of the present disclosure. For example, the operations may be composed of various substeps, or may be performed in conjunction with other operations described herein.

At operation 300, the system provides a zipper extending along at least a first side and a second side of the protective case. In some cases, the operations of this step may refer to, or be performed by, a zipper as described with reference to FIGS. 1 and 2.

At operation 305, the system provides a zipper slider configured to be located along the second side when the zipper is fully closed. In some cases, the operations of this step may refer to, or be performed by, a zipper slider as described with reference to FIGS. 1 and 2.

At operation 310, the system provides an inner flap that extends in a first direction parallel to the first side from the second side to a third side of the protective case opposite the second side, where the inner flap includes an extension of the inner flap adjacent to the second side, where the extension extends in a second direction parallel to the second side such that a width of the inner flap adjacent to the second side is greater than a width of the inner flap adjacent to the third side. In some cases, the operations of this step may refer to, or be performed by, an inner flap as described with reference to FIGS. 1 and 2.

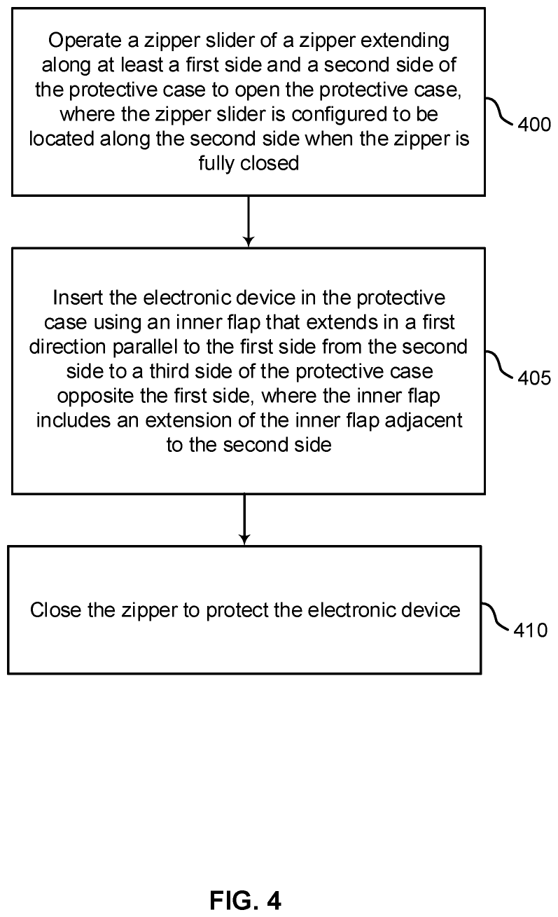

FIG. 4 shows an example of a process for using an apparatus for protecting an electronic device according to aspects of the present disclosure. Generally, these operations may be performed according to the methods and processes described in accordance with aspects of the present disclosure. For example, the operations may be composed of various substeps, or may be performed in conjunction with other operations described herein.

At operation 400, a user operates a zipper slider of a zipper extending along at least a first side and a second side of the protective case to open the protective case, where the zipper slider is configured to be located along the second side when the zipper is fully closed. In some cases, the operations of this step may refer to, or be performed by, a zipper as described with reference to FIGS. 1 and 2.

At operation 405, the user inserts the electronic device in the protective case using an inner flap that extends in a first direction parallel to the first side from the second side to a third side of the protective case opposite the second side, where the inner flap includes an extension of the inner flap adjacent to the second side, where the extension extends in a second direction parallel to the second side such that a width of the inner flap adjacent to the second side is greater than a width of the inner flap adjacent to the third side. In some cases, the operations of this step may refer to, or be performed by, an inner flap as described with reference to FIGS. 1 and 2.

At operation 410, after inserting the electronic device, the user may close the zipper to protect the electronic device. For example, closing the zipper may prevent dust or moisture from entering the protective case, and may also further protect the electronic device from physical damage in case of a collision.

Accordingly, the present disclosure includes the following embodiments.

An apparatus for protecting an electronic device is described. Embodiments of the apparatus may include a zipper extending along at least a first side and a second side of the protective case, a zipper slider configured to be located along the second side when the zipper is fully closed, an inner flap that extends in a first direction parallel to the first side from the second side to a third side of the protective case opposite the second side, and an extension of the inner flap adjacent to the second side, wherein the extension extends in a second direction parallel to the second side such that a width of the inner flap adjacent to the second side is greater than a width of the inner flap adjacent to the third side.

A method of manufacturing a protective case for an electronic device is described. The method may include providing a zipper extending along at least a first side and a second side of the protective case, providing a zipper slider configured to be located along the second side when the zipper is fully closed, providing an inner flap that extends in a first direction parallel to the first side from the second side to a third side of the protective case opposite the second side, and providing an extension of the inner flap adjacent to the second side, wherein the extension extends in a second direction parallel to the second side such that a width of the inner flap adjacent to the second side is greater than a width of the inner flap adjacent to the third side.

A process for using a protective case for an electronic device is described. The process may include using a zipper extending along at least a first side and a second side of the protective case, using a zipper slider configured to be located along the second side when the zipper is fully closed, using an inner flap that extends in a first direction parallel to the first side from the second side to a third side of the protective case opposite the second side, and using an extension of the inner flap adjacent to the second side, wherein the extension extends in a second direction parallel to the second side such that a width of the inner flap adjacent to the second side is greater than a width of the inner flap adjacent to the third side.

In some examples, the inner flap is configured to separate at least a portion of the electronic device from the zipper slider. In some examples, the extension of the inner flap is configured to separate the zipper slider from the electronic device when the zipper is fully closed. In some examples, the zipper slider is located along the third side when the zipper is fully open. In some examples, the inner flap is not located between the zipper slider and the electronic device when the zipper is fully open.

In some examples, the inner flap comprises an elastic material configured to enable insertion of the electronic device in the protective case with at least one edge of the electronic device covered by the inner flap. In some examples, the zipper extends across a full length of the first side, and along a partial length of the second side and a partial length of the third side. Some examples of the apparatus, method, and process described above may further include a soft lining located on at least one interior surface of the protective case.

The description and drawings described herein represent example configurations and do not represent all the implementations within the scope of the claims. For example, the operations and steps may be rearranged, combined or otherwise modified. Also, structures and devices may be represented in the form of block diagrams to represent the relationship between components and avoid obscuring the described concepts. Similar components or features may have the same name but may have different reference numbers corresponding to different figures.

Some modifications to the disclosure may be readily apparent to those skilled in the art, and the principles defined herein may be applied to other variations without departing from the scope of the disclosure. Thus, the disclosure is not limited to the examples and designs described herein, but is to be accorded the broadest scope consistent with the principles and novel features disclosed herein.

The described methods may be implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. A general-purpose processor may be a microprocessor, a conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Thus, the functions described herein may be implemented in hardware or software and may be executed by a processor, firmware, or any combination thereof. If implemented in software executed by a processor, the functions may be stored in the form of instructions or code on a computer-readable medium.

Computer-readable media includes both non-transitory computer storage media and communication media including any medium that facilitates transfer of code or data. A non-transitory storage medium may be any available medium that can be accessed by a computer. For example, non-transitory computer-readable media can comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, connecting components may be properly termed computer-readable media. For example, if code or data is transmitted from a web site, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” may be based on both condition A and condition B. In other words, the phrase “based on” shall be construed to mean “based at least in part on.” Also, the words “a” or “an” indicate “at least one.”

What is claimed is:

1. A protective case for an electronic device, the protective case comprising:
a zipper extending along a first side and at least a part of a second side of the protective case;
a zipper slider configured to be located along the second side when the zipper is fully closed;
an inner flap that extends in a first direction parallel to the first side from the second side to a third side of the protective case opposite the second side; and
an extension of the inner flap adjacent to the second side, wherein the extension extends in a second direction parallel to the second side such that a width of the inner flap adjacent to the second side is greater than a width of the inner flap adjacent to the third side.

2. The protective case of claim 1, wherein:
the inner flap is configured to separate at least a portion of the electronic device from the zipper slider.

3. The protective case of claim 1, wherein:
the extension of the inner flap is configured to separate the zipper slider from the electronic device when the zipper is fully closed.

4. The protective case of claim 1, wherein:
the zipper slider is located along the third side when the zipper is fully open; and
the inner flap is not located between the zipper slider and the electronic device when the zipper is fully open.

5. The protective case of claim 1, wherein:
the inner flap comprises an elastic material configured to enable insertion of the electronic device in the protective case with at least one edge of the electronic device covered by the inner flap.

6. The protective case of claim 1, wherein:
the zipper extends across a full length of the first side, and along a partial length of the second side and a partial length of the third side.

7. The protective case of claim 1, further comprising:
a soft lining located on at least one interior surface of the protective case.

8. A method of manufacturing a protective case for an electronic device, the method comprising:
providing a zipper extending along at least a first side and a second side of the protective case;
providing a zipper slider configured to be located along the second side when the zipper is fully closed;
providing an inner flap that extends in a first direction parallel to the first side from the second side to a third side of the protective case opposite the second side; and
wherein the inner flap comprises an extension of the inner flap adjacent to the second side, wherein the extension extends in a second direction parallel to the second side such that a width of the inner flap adjacent to the second side is greater than a width of the inner flap adjacent to the third side.

9. The method of claim 8 wherein:
the inner flap is configured to separate at least a portion of the electronic device from the zipper slider.

10. The method of claim 8, wherein:
the extension of the inner flap is configured to separate the zipper slider from the electronic device when the zipper is fully closed.

11. The method of claim 8, wherein:
the zipper slider is located along the third side when the zipper is fully open; and
the inner flap is not located between the zipper slider and the electronic device when the zipper is fully open.

12. The method of claim 8, wherein:
the inner flap comprises an elastic material configured to enable insertion of the electronic device in the protective case with at least one edge of the electronic device covered by the inner flap.

13. The method of claim 8, wherein:
the zipper extends across a full length of the first side, and along a partial length of the second side and a partial length of the third side.

14. The method of claim 8, further comprising:
providing a soft lining located on at least one interior surface of the protective case.

15. A method of using a protective case for an electronic device, the method comprising:
operating a zipper slider of a zipper extending along at least a first side and a second side of the protective case to open the protective case, wherein the zipper slider is configured to be located along the second side when the zipper is fully closed;
inserting the electronic device in the protective case using an inner flap that extends in a first direction parallel to the first side from the second side to a third side of the protective case opposite the second side, wherein the inner flap comprises an extension of the inner flap adjacent to the second side, wherein the extension extends in a second direction parallel to the second side such that a width of the inner flap adjacent to the second side is greater than a width of the inner flap adjacent to the third side.

16. The method of claim 15, wherein:
the inner flap is configured to separate at least a portion of the electronic device from the zipper slider.

17. The method of claim 15, wherein:
the extension of the inner flap is configured to separate the zipper slider from the electronic device when the zipper is fully closed.

18. The method of claim 15, wherein:
the zipper slider is located along the third side when the zipper is fully open; and
the inner flap is not located between the zipper slider and the electronic device when the zipper is fully open.

19. The method of claim 15, wherein:
the inner flap comprises an elastic material configured to enable insertion of the electronic device in the protective case with at least one edge of the electronic device covered by the inner flap.

20. The method of claim 15, wherein:
the zipper extends across a full length of the first side, and along a partial length of the second side and a partial length of the third side.
